(19) United States
(12) Patent Application Publication
(10) Pub. No.: US 2016/0307639 A1
(43) Pub. Date: Oct. 20, 2016

(54) SEMICONDUCTOR DEVICE AND METHOD OF DRIVING THE SAME

(71) Applicant: SK hynix Inc., Gyeonggi-do (KR)

(72) Inventor: Soo-Bin LIM, Gyeonggi-do (KR)

(21) Appl. No.: 14/829,348

(22) Filed: Aug. 18, 2015

(30) Foreign Application Priority Data
Apr. 14, 2015 (KR) 10-2015-0052430

(51) Int. Cl. G11C 17/16; G11C 17/18; G06F 9/44; G11C 29/00

(52) U.S. Cl. CPC G11C 17/16; G11C 29/78; G11C 17/18; G06F 9/4403

(57) ABSTRACT

A semiconductor device may include: a control block suitable for generating a boot-up select signal in response to a boot-up mode signal and a fuse select signal; and a fuse block suitable for performing a program operation of rupturing one or more first fuse cells among a plurality of fuse cells in response to the fuse select signal, and performing a boot-up operation on a partial fuse region including the one or more first fuse cells in response to the boot-up select signal.

### CROSS-REFERENCE TO RELATED APPLICATIONS

The present application claims priority of Korean Patent. Application No. 10-2015-0052430, filed on Apr. 14, 2015, which is incorporated herein by reference in its entirety.

### BACKGROUND

1. Field

Exemplary embodiments of the present invention relate to a semiconductor design technology, and more particularly, to a semiconductor device and a method of driving the same.

2. Description of the Related Art

Semiconductor devices use fuse circuits to store information required for operation of memory chips, such as setting information and repair information. For example, semiconductor memory devices may use fuse circuits to replace defective memory cells or control various mode selections. A fuse circuit that is used to replace a defective memory cell will be used as an example. A fuse circuit may store an address for a defective memory cell and/or an address for a redundancy memory cell so that a redundancy memory cell is accessed instead of a defective memory cell.

One example of a fuse circuit is a laser fuse. A laser fuse stores high or low data depending on whether the laser fuse is cut. The laser fuse may be cut in the wafer state but not in the package state.

In order to address such concerns, an E-fuse may be used. E-fuse arrays (ARE) are widely used, E-fuses resemble transistors, and store information by rupturing a gate dielectric layer by applying a high voltage to the gate region.

The fuse data stored in an ARE is sensed during a boot-up operation following a power-up operation, and the sensed fuse data is stored in a storage circuit such as a register.

FIG. 1 is a block diagram illustrating a conventional semiconductor device.

Referring to FIG. 1, the semiconductor device includes a periodic signal generation unit 10, a driving signal generation unit 20, a fuse array unit 30, and a fuse storage unit 40.

The periodic signal generation unit 10 generates a periodic signal CLK_SIG having a predetermined period in response to a boot-up signal BT or reboot-up signal RBT.

The driving signal generation unit 20 may count the toggling number of the periodic signal CLK_SIG, The driving signal generation unit 20 generates fuse driving signals WL<1:I> and BL<1:3> and latch driving signals LT<1:N> in response to the toggling number of the periodic signal CLK_SIG, The plurality of fuse driving signals WL<1:I> and BL<1:J> and latch driving signals LT<1:N> are selectively activated in response to the counted value.

The fuse array unit 30 includes fuse cells C1 to CN arranged at the respective intersections between word lines WL_1 to WL_I and bit lines BL_1 to BL_J. The fuse array unit 30 performs a program operation of rupturing part or all of the fuse cells C1 to CN in response to a fuse select signal MRD<1:M> and a rupture enable signal RUP_EN. Furthermore, the fuse array unit 30 sequentially outputs fuse data F_DATA<1:N> from the fuse cells C1 to CN in response to the fuse driving signals WL<1:I> and BL<1:J>.

The fuse storage unit 40 includes latches LAT1 to LATN. The fuse storage unit 40 sequentially stores fuse data F_DATA<1:N>, which are sequentially outputted from the fuse cells C1 to CN, in the latches LAT1 to LATN, respectively, in response to the latch driving signals LT<1:N>.

Hereafter, an operation of the semiconductor device having the above-described configuration will be described.

First, the semiconductor device performs a program operation. The program operation may be performed during a test mode. The program operation may be performed as follows. The fuse array unit 30 ruptures some or all of the fuse cells C1 to CN in response to the fuse select signal MRD<1:M> and the rupture enable signal RUP_EN. The fuse select signal MRD<1:N> may include an address signal indicating a some or all of the fuse cells C1 to CN in the fuse array unit 30.

Then, the semiconductor device performs a boot-up operation. The boot-up operation may be performed during an initial operation period of a normal mode. The boot-up operation may be performed as follows. The periodic signal generation unit 10 generates the periodic signal CLK_SIG in response to the boot-up signal BT, and the driving signal generation unit 20 generates the fuse driving signals WL<1:I> and BL<1:J> and the latch driving signals LT<1:N> in response to the periodic signal CLK_SIG. Then, the fuse array unit 30 may sequentially output the fuse data F_DATA<1 N> from the fuse cells C1 to CN according to a predetermined sequence, in response to the fuse driving signals WL<1:I> and BL<1:J>, and the fuse storage unit 40 sequentially stores the fuse data F_DATA<1:N> in the latches LAT1 to LATH, respectively, according to the predetermined sequence.

Then, the semiconductor device performs a reboot-up operation. The reboot-up operation may be performed during a different test mode than the one where the program operation is performed. The reboot-up operation may be performed to verify whether the program operation was properly performed, or to update the fuse data F_DATA<1:N>. For reference, when the reboot-up operation performed to update the fuse data F_DATA<1:N> an additional program operation may be performed prior to the reboot-up operation. The reboot-up operation may be performed as follows. The periodic signal generation unit 10 generates the periodic signal CLK_SIG in response to the reboot-up signal RBT, and the driving signal generation unit 20 generates the fuse driving signals WL<1:I> and BL<1:J> and the latch driving signals LT<1:N> in response to the periodic signal CLK_SIG. Then, the fuse array unit 30 may sequentially output the fuse data F_DATA<1:N> from the fuse cells C1 to CN according to a predetermined sequence, in response to the fuse driving signals WL<1:I> and BL<1:J>, and the fuse storage unit 40 sequentially stores the fuse data F_DATA<1:N> in the latches LAT1 to LATN, respectively, according to the predetermined sequence.

When the fuse data F_DATA<1:N> are required, the semiconductor device having the above-described configuration may not directly read the fuse data F_DATA<1:N> from the fuse array unit 30, but read the fuse data F_DATA<1:N> stored in the fuse storage unit 40, thereby improving the operation performance.

However, following concerns remain.

When performing the reboot-up operation, the semiconductor device may output all of the fuse data F_DATA 1:N> from the fuse array unit 30 in the same manner as the boot-up operation, and store all of the fuse data F_DATA<1:N> in the fuse storage unit 40. In other words, the semiconductor device performs the reboot-up operation on the entire region of the fuse array unit 30. Therefore, the semiconductor device requires a lot of time for performing the reboot-up operation.

### SUMMARY

Various embodiments are directed to a semiconductor device capable of performing a reboot-up operation on only some fuse cells.

In an embodiment, a semiconductor device may include: a control block suitable for generating a boot-up select signal in response to a boot-up mode signal and a fuse select signal; and a fuse block suitable for performing a program operation of rupturing one or more first fuse cells among a plurality of fuse cells in response to the fuse select signal, and performing a boot-up operation on a partial fuse region including the one or more first fuse cells in response to the boot-up select signal.

A unique number may be assigned to each of the fuse cells, and the partial fuse region may include the one or more first fuse cells and one or more second fuse cells having a later number than the one or more first fuse cells.

The control block may generate a periodic signal in response to the boot-up mode signal, and the fuse block may perform the boot-up operation in response to the periodic signal.

The fuse block may include: a fuse driving unit suitable for generating a latch driving signal and a fuse driving signal corresponding to the partial fuse region in response to the boot-up select signal and the periodic signal; and a fuse circuit unit suitable for performing the boot-up operation on the partial fuse region in response to the fuse driving signal and the latch driving signal.

The fuse driving unit may include: a counter suitable for generating a counting signal corresponding to the first fuse cells in response to the periodic signal and the boot-up select signal; and a decoding unit suitable for generating the fuse driving signal and the latch driving signal by decoding the counting signal.

The counter may include a plurality of flip-flops corresponding one-to-one to a plurality of bits included in the counting signal, and suitable for setting an initial level of the counting signal in response to in a plurality of bits included in the boot-up select signal.

The fuse circuit unit may perform the program operation of rupturing the one or more first fuse cells in response to the fuse select signal and a rupture enable signal and the program operation and the boot-up operation are performed in different test modes.

The fuse circuit unit may include: a fuse array unit comprising the plurality of fuse cells, and suitable for performing the program operation on the one or more first fuse cells in response to the fuse select signal and the rupture enable signal, and outputting partial fuse data corresponding to the partial fuse region in response to the fuse driving signal; and a fuse storage unit comprising a plurality of latches corresponding one-to-one to the plurality of fuse cells, and suitable for storing the partial fuse data in corresponding latches in response to the latch driving signal.

In an embodiment, a semiconductor device n ay include: a boot-up select signal generation unit suitable for generating a boot-up select signal in response to a boot-up mode signal and a fuse select signal; a fuse driving unit suitable for sequentially activating Kth to Nth fuse driving signals, and sequentially activating Kth to Nth latch driving signals, in response to the boot-up select signal, where N is a natural number greater than or equal to 2 and K is a natural number between 1 and N; and a fuse circuit unit suitable for performing a program operation of rupturing one or more fuse cells including the Kth fuse cell in response to the fuse select signal, and performing a boot-up operation on the Kth to Nth fuse cells in response to the Kth to Nth fuse driving signals.

The semiconductor device may further include a periodic signal generation unit suitable for generating a periodic signal in response to the boot-up mode signal.

The fuse driving unit may include: a counter suitable for generating a counting signal corresponding to the Kth to Nth fuse cells in response to the periodic signal and the boot-up select signal; and a decoding unit suitable for generating the Kth to Nth fuse driving signals and the Kth to Nth latch driving signals by decoding the counting signal.

The counter may include a plurality of flip-flops corresponding one-to-one to a plurality of bits included in the counting signal, and suitable for setting an initial level of the counting signal in response to a plurality of bits included in the boot-up select signal.

The fuse circuit unit may perform the program operation of rupturing the one or more fuse cells in response to the fuse select signal and a rupture enable signal, and the program operation and the boot-up operation are performed in different test modes.

The fuse circuit unit may include: a fuse array unit comprising the first to Nth fuse cells, and suitable for performing the program operation on the one or more fuse cells including the Kth fuse cell in response to the fuse select signal and the rupture enable signal, and outputting the Kth to Nth fuse data corresponding to the Kth to Nth fuse cells in response to the Kth to Nth fuse driving signals; and a fuse storage unit comprising first to Nth latches corresponding one-to-one to the first to Nth fuse cells, and suitable for storing the Kth to Nth fuse data in the Kth to Nth latches in response to the Kth to Nth latch driving signals.

In an embodiment, a method of driving a semiconductor device may include: performing a boot-up operation on an entire fuse region including a plurality of fuse cells during a normal mode; performing a program operation of rupturing one or more fuse cells during a first test mode; and performing a first reboot-up operation on a partial fuse region including the one or more fuse cells during a second test mode.

The performing of the program operation may include: entering the first test mode; and rupturing the one or more fuse cells in response to a fuse select signal.

The performing of the first reboot-up operation may include: entering the second test mode; setting an initial value of a counting signal in response to a fuse select signal; generating the counting signal by counting a periodic signal by a value corresponding to the partial fuse region from the initial value; generating a fuse driving signal and a latch driving signal by decoding the counting signal; outputting fuse data from the partial fuse region in response to the fuse driving signal; and storing the fuse data outputted from the partial fuse region in a partial latch region in response to the latch driving signal.

The performing of the boot-up operation may include: entering the normal mode; generating a counting signal by counting a periodic signal; generating a fuse driving signal and a latch driving signal by decoding the counting signal; outputting fuse data from the entire fuse region in response to the fuse driving signal; and storing the fuse data outputted from the entire fuse region in an entire latch region in response to the latch driving signal.

The method may further include performing a second reboot-up operation on the entire fuse region during a third test mode.

The performing of the second reboot-up operation may include: entering the third test mode; generating a counting signal by counting a periodic signal corresponding to the entire fuse region; generating a fuse driving signal and a latch driving signal by decoding the counting signal; outputting fuse data from the entire fuse region in response to the fuse driving signal; and storing the fuse data outputted from the entire fuse region in an entire latch region in response to the latch driving signal.

### BRIEF DESCRIPTION OF THE DRAWINGS

FIG. 1 is a block diagram illustrating a conventional semiconductor device.

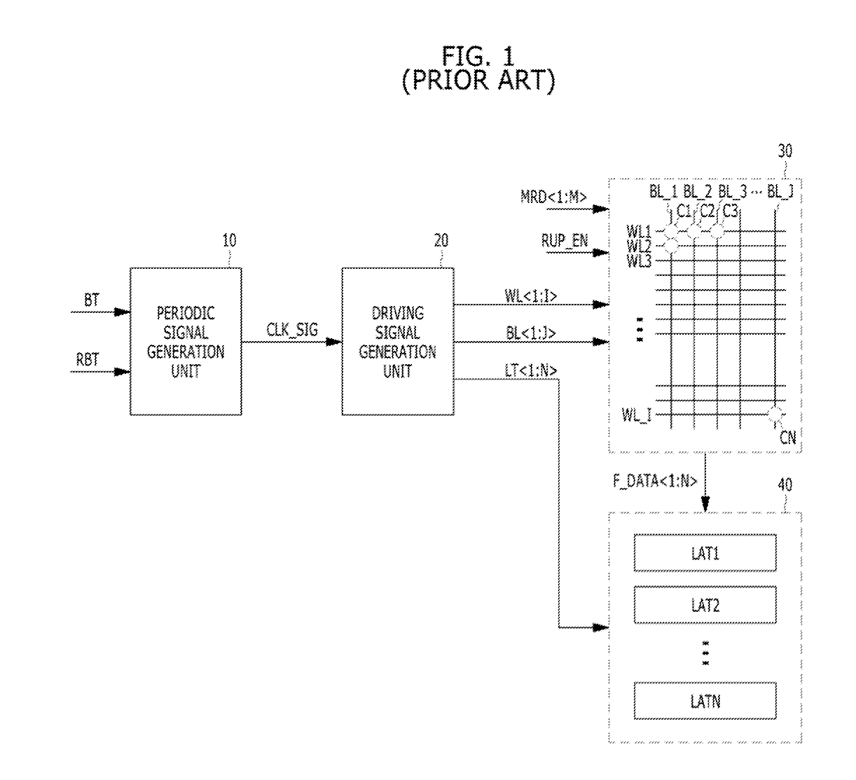

FIG. 2 is a block diagram illustrating a semiconductor memory device in accordance with an embodiment of the present invention.

FIG. 3 is a detailed block diagram illustrating a control block shown in FIG. 2.

FIG. 4 is a detailed block diagram illustrating a fuse block shown in FIG. 2.

FIG. 5 is a detailed block diagram illustrating a fuse driving unit shown in FIG. 4.

FIG. 6 is a circuit diagram illustrating a counter shown in FIG. 5.

FIG. 7 is a detailed block diagram illustrating a fuse circuit unit shown in FIG. 4.

FIGS. 8 and 9 are timing diagrams for describing a method of driving the semiconductor device illustrated in FIG. 2.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art, Throughout the disclosure, like reference numerals refer to like parts throughout the various figures and embodiments of the present invention.

The drawings are not necessarily to scale and, in some instances, proportions may have been exaggerated to clearly illustrate features of the embodiments. It is also noted that in this specification, “connected/coupled” refers to one component not only directly coupling another component, but also indirectly coupling another component through an intermediate component. In addition, a singular form may include a plural form as long as it is not specifically mentioned.

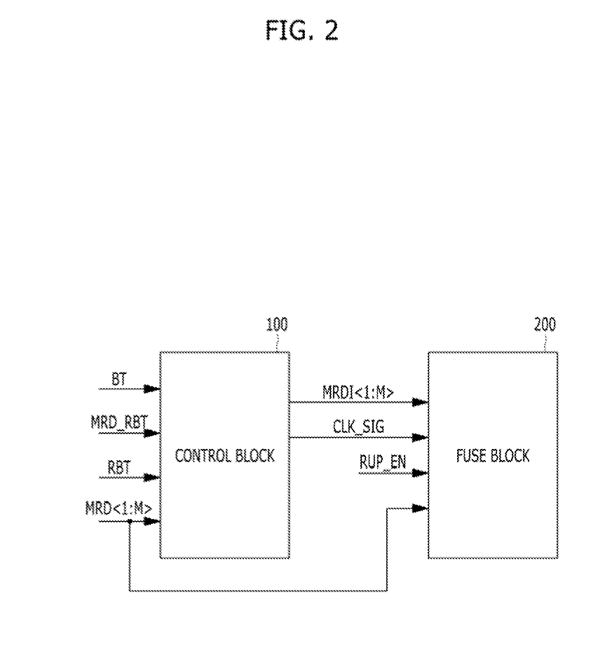

FIG. 2 is a block diagram illustrating a semiconductor memory device in accordance with an embodiment of the present invention.

Referring to FIG. 2, the semiconductor device may include a control block 100 and a fuse block 200.

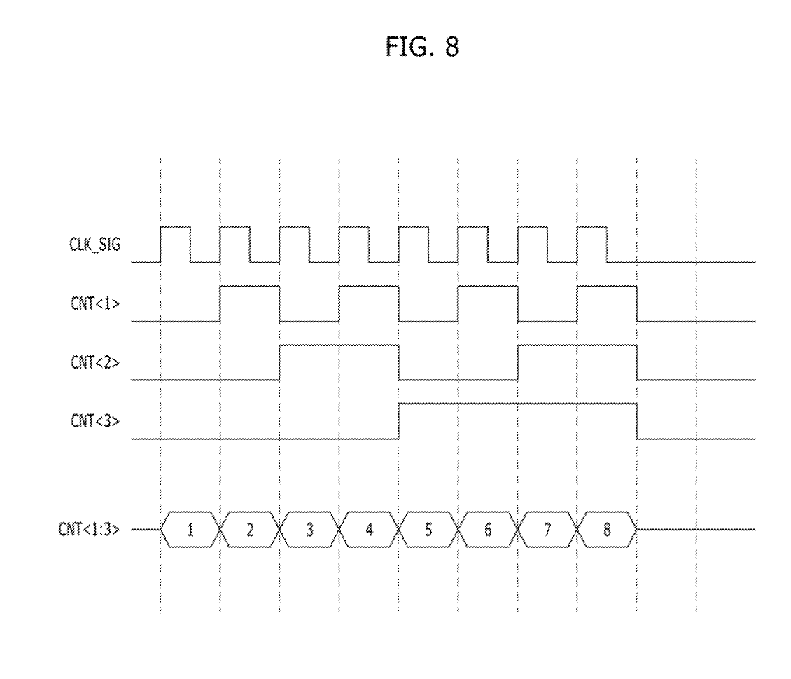

The control block 100 may generate a boot-up select signal MRDI<1:M> and a periodic signal CLK_SIG having a predetermined period in response to a first boot-up signal BT, a second boot-up signal MRD_RBT a third boot-up signal RBT, and a fuse select signal MRD<1:M>. For example, the control block 100 may generate the periodic signal CLK_SIG in response to the first boot-up signal BT, the second boot-up signal MRD RBT, and the third boot-up signal RBT, and generate the boot-up select signal MRDI<1:M> in response to the second boot-up signal MRD_RBT and the fuse select signal MRD<1:M>. In particular, the control block 100 may control a Memory Repair Data (MRD) reboot-up operation of the fuse block 200 in response to the boot-up select signal MRDI<1:M>. The MRD reboot-up operation may indicate a boot-up operation which is not performed on the entire region of first to Nth fuse cells C1 to CN included in the fuse block 200, but performed on a partial region of the first to Nth fuse cells C1 to CN. Here, N and M are natural numbers greater than or equal to 2. The first to Nth fuse cells C1 to CN will be described below with reference to FIG. 7.

The first boot-up signal BT may be used to control a boot-up operation for the entire fuse region after a power-up operation of the semiconductor device. The second boot-up signal MRD RBT may be used to control the MRD reboot-up operation and be generated during a second test mode. The third boot-up signal RBT may be used to control the reboot-up operation for the entire fuse region and be generated during a third test mode. The fuse select signal MRD<1:M> may include an address signal indicating one or more of the first to Nth fuse cells C1 to CN included in the fuse block 200.

The fuse block 200 may perform a program operation of rupturing one or more of the fuse cells in response to the fuse select signal MRD<1:M> and a rupture enable signal RUP_EN. For example, the program operation may be performed in a first test mode. The fuse block 200 may perform the boot-up operation, the MRD reboot-up operation, or the reboot-up operation in response to the boot-up select signal MRDI<1:M> and the periodic signal CLK_SIG.

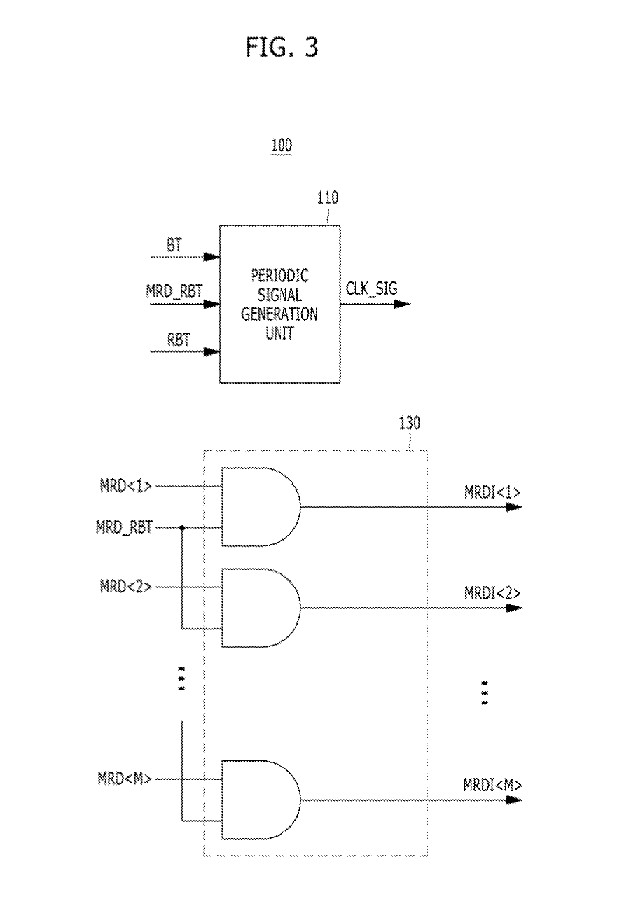

FIG. 3 is a detailed block diagram illustrating the control block 100 shown in FIG. 2.

Referring to FIG. 3, the control block 100 may include a periodic signal generation unit 110 and a boot-up select signal generation unit 130.

The periodic signal generation unit 110 may generate the periodic signal CLK SIG having a predetermined period in response to the first boot-up signal BT, the second boot-up signal MRD_RBT, and the third boot-up signal RBT. For example, the periodic signal generation unit 110 may generate the periodic signal CLK SIG during a period in which the first boot-up signal BT, the second boot-up signal MRD_RBT or the third boot-up signal RBT are activated. The periodic signal CLK_SIG may include a clock signal for example.

The periodic signal generation unit 110 may include a delay unit which is not illustrated in FIG. 2. For example, the delay unit may generate a delayed boot-up signal by delaying the second boot-up signal MRD_RBT by a predetermined time. In this case, the periodic signal generation unit 110 may generate the periodic signal CLK_SIG during a period in which the delayed boot-up signal is activated. This is in order to generate the periodic signal CLK_SIG after the boot-up select signal MRDI<1:M> is generated.

The boot-up select signal generation unit 130 may generate the boot-up select signal MRDI<1:M> in response to the second boot-up signal MRD_RBT and the fuse select signal MRD<1:M>. For example, when the fuse select signal MRD<1:M> may have M bits, the boot-up select signal generation unit 130 may include M AND gates for generating the boot-up select signal MRDI<1:M> having M bits in response to the respective bits of the fuse select signal MRD<1:M> and the second boot-up signal MRD_RBT. When it is assumed that M is 4, the four-bit fuse select signal MRD<1:4> is set to ‘1100’ and the second boot-up signal MRD RBT is activated to a high level, four AND gates may output ‘1’, ‘1’, ‘0’, and ‘0’, respectively. As a result, the boot-up select signal generation unit 130 may generate the boot-up select signal MRDI<1:4> of ‘1100’.

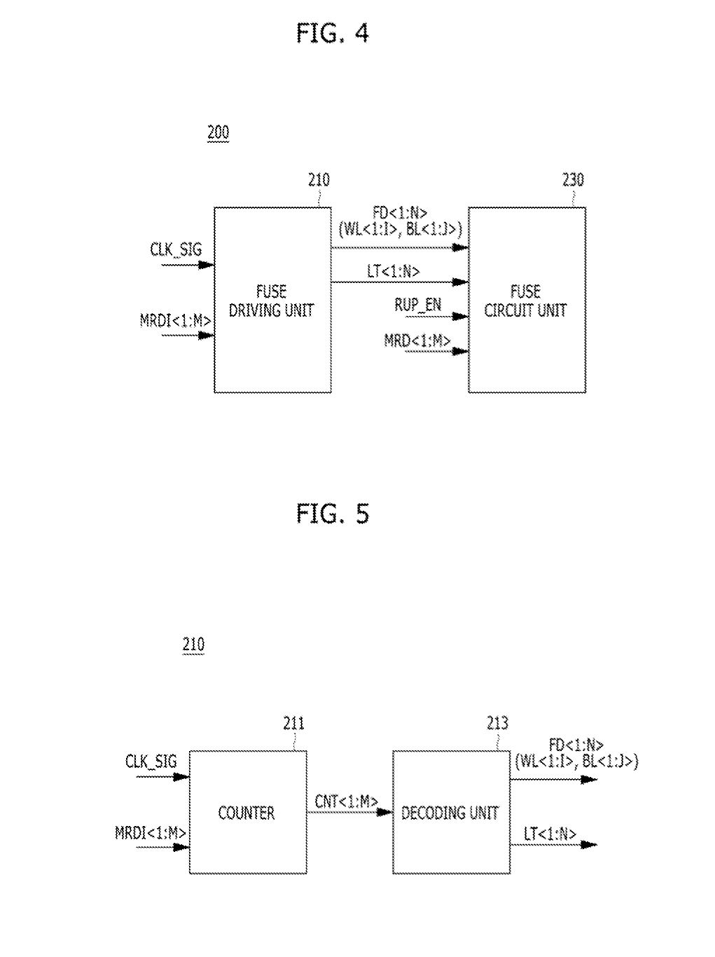

FIG. 4 is a detailed block diagram illustrating the fuse block 200 shown in FIG. 2.

Referring to FIG. 4, the fuse block 200 may include a fuse driving unit 210 and a fuse circuit unit 230.

The fuse driving unit 210 may generate first to Nth fuse driving signals FD<1:N> and first to Nth latch driving signals LT<1:N> in response to the periodic signal CLK_SIG and the boot-up select signal MRDI<1:M>. The first to Nth fuse driving signals FD<1:N> may include first to Ith word line driving signals L<1:I> and first to ith bit line driving signals BL<1:J> according to an arrangement structure of the first to Nth fuse cells C1 to CN, i.e., I*J=N. Hereafter, however, the first to Nth fuse driving signals FD<1:N> will be referred to as the first to Nth fuse driving signals FD<1:N> corresponding to the number N of the first to Nth fuse cells C1 to CN, for convenience.

For example, the fuse driving unit 210 may sequentially activate the fuse driving signals FD<1:N> and the latch driving signals LT<1:N> corresponding to the entire fuse region, in response to the periodic signal CLK_SIG and the boot-up select signal MRDI<1:M>, and sequentially activate Kth to Nth fuse driving signals FD<K:N> and Kth to Nth latch driving signals LT<K:N> corresponding to the partial fuse region, where K is a natural number between 1 and N.

The fuse circuit unit 230 may perform the program operation on fuse cells corresponding to the fuse select signal MRD<1:N> among the first to Nth fuse cells C1 to CN, in response to the fuse select signal MRD<1:M> and the rupture enable signal RUP_EN, Furthermore, the fuse circuit unit 230 may perform the boot-up operation or the reboot-up operation on the entire fuse region in response to the first to Nth fuse driving signals FD<1:N> and the first to Nth latch driving signals LT<1:N>, or perform the MRD reboot-up operation on the partial fuse region in response to the Kth to Nth fuse driving signals FD<K:N> and the Kth to Nth latch driving signals LT<K:N>.

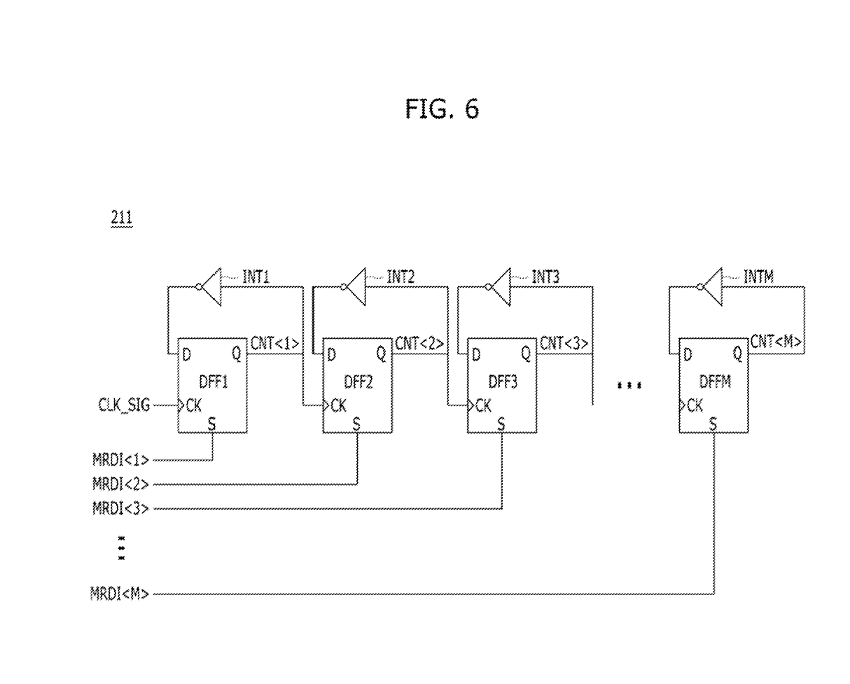

FIG. 5 is a detailed block diagram illustrating the fuse driving unit 210 shown in FIG. 4.

Referring to FIG. 5, the fuse driving unit 210 may include a counter 211 and a decoding unit 213.

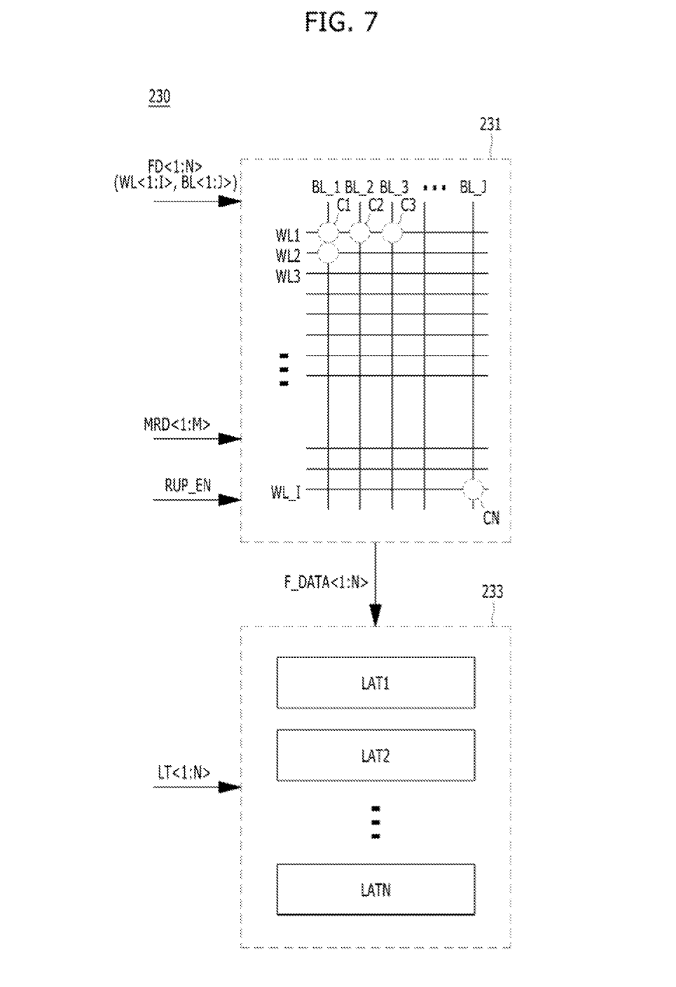

The counter 211 may generate a counting signal CNT<1:M> in response to the periodic signal CLK_SIG and the boot-up select signal MRDI<1:M>. That is, the counter 211 may count the toggling number of the periodic signal CLK_SIG, and output the counting signal CNT<1:M>. For example, the counter 211 may include an M-bit counter, and generate the counting signal CNT<1:M> having a counting value which sequentially increases from 1 to N, where N is 2^{M}. The counter 211 may set an initial value of the counting signal CNT<1:M> in response to the boot-up select signal MRDI<1:M>. For example, when it is assumed that M is 3 and the three-bit boot-up select signal MRDI<1:3> is set to ‘101’, the counter 211 may set the initial value of the counter to ‘010’ in response to the boot-up select signal MRDI<1:3> of ‘010’. In other words, the counting signal CNT<1:3> may have an initial value of ‘000’ as a default value, but have an initial value of ‘010’ in response to the boot-up select signal MRDI<1:3>. When the counting signal CNT<1:3> has the initial value of ‘010’, the counter 211 may start counting from ‘3’, instead of ‘1’. The counter 211 will be described below in more detail with reference to FIG. 6.

The decoding unit 213 may generate the first to Nth fuse driving signals FD<1:N> and the first to Nth latch driving signals LT<1:N> in response to the counting signal CNT<1:11>. For example, suppose that M is 3 and the initial value of the counting signal CNT<1:3> is set to ‘010’. In this case, the decoding unit 213 may generate the third fuse driving signal FD<3> corresponding to the third fuse cell among the first to Nth fuse cells C1 to CN and the third latch driving signal LT<3> corresponding to the third latch among the first to Nth latches LAT1 to LATN, in response to the counting signal CNT<1:3>. Then, the decoding unit 213 may sequentially generate the fourth to Nth fuse driving signals FD<4:N> and the fourth to Nth latch driving signals LT<4:N> in response to the counting signal CNT<1:3> which sequentially increases. Although not illustrated, the decoding unit 213 may include first and second decoders. The first decoder may generate the first to Nth fuse driving signals FD<1:N> in response to the counting signal CNT<1:M>, and the second decoder may generate the first to Nth latch driving signals LT<1:N> in response to the counting signal CNT<1:M>.

FIG. 6 is a circuit diagram illustrating the counter 211 shown in FIG. 5.

Referring to FIG. 6, the counter 211 may include first to Mth flip-flops DFF1 to DFFM which correspond one-to-one to the respective bits of the counting signal CNT<1:M>. The first to Mth flip-flops DFF1 to DFFM may set the initial value of the counting signal CNT<1:M> in response to the boot-up select signal' MRDI<1:M>. For example, when M is 3, and the counter 211 generates the three-bit counting signal CNT<1:3> the first to third flip-flops DFF1 to DFF3 may output the counting signal CNT<1:3> having an initial value of ‘000’ in response to the boot-up select signal MRDI<1:3> of ‘000’, or output the counting signal CNT<1:3> having an initial value of ‘0111’ in response to the boot-up select signal MRDI<1:3> of ‘011’.

Each of the first to Mth flip-flops DFF1 to DFFM may include a data terminal D, a clock terminal CK, a set terminal S, and an output terminal Q. The data terminal D of the first flip-flop DFF1 may receive the first output signal CNT<1> fed back from its output terminal Q through a first inverter INT1. The clock terminal CK of the first flip-flop DFF1 may receive the periodic signal CLK_SIG. The set terminal of the first flip-flip DFF1 may receive the first bit MRDI<1> of the boot-up select signal' MRDI<1:M>.

The data terminal D of the second flip-flop DFF2 n ay receive the second output signal CNT<2> fed back from its output terminal Q through a second inverter INT2. The clock terminal CK of the second flip-flop DFF2 may receive the first output signal CNT<1> outputted from the first flip-flop DFF1. The set terminal of the second flip-flip DFF2 may receive the second bit MRDI<2> of the boot-up select signal MRDI<1:M>.

The data terminal D of the third flip-flop DFF3 may receive the third output signal CNT<3> fed back from its output terminal Q through a third inverter INT3. The dock terminal CK of the third flip-flop DFF3 may receive the second output signal CNT<2> outputted from the second flip-flop DFF2. The set terminal S of the third flip-flip DFF3 may receive the third bit MRDI<3> of the boot-up select signal MRDI<1:M>.

The data terminal D of the Mth flip-flop DFFM may receive the Mth output signal CNT<M> fed back from its output terminal Q through an Mth inverter INTM. The clock terminal CK of the Mth flip-flop DFFM may receive the (M−1)th output signal CNT<M−1> outputted from the (M−1)th flip-flop. The set terminal S of the Mth flip-flip DFFM may receive the Mth bit MRDI<M> of the boot-up select signal MRDI<1:M>.

FIG. 7 is a detailed block diagram illustrating the fuse circuit unit 230 shown in FIG. 4.

Referring to FIG. 7, the fuse circ it unit 230 may include a fuse array unit 231 and a fuse storage unit 233.

The fuse array unit 231 may include first to Nth fuse cells C1 to CN arranged at the respective intersections between first to Ith word lines WL_1 to WL_I and first to Jth bit lines BL_1 to BL_1. The fuse array unit 231 may perform the program operation in response to the rupture enable signal RUP_EN and the fuse select signal MRD<1:M>. Furthermore, the fuse array unit 231 may sequentially output the first to Nth fuse data F_DATA<1:N> from the first to Nth fuse cells C1 to CN in response to the first to Nth fuse driving signals FD<1:N>. For example, the fuse array unit 231 may sequentially output the first to Nth fuse data F_DATA<1:N> from the entire fuse region including the first to Nth fuse cells C1 to CN in response to the first to Nth fuse driving signals FD<1:N> which are sequentially activated during the boot-up operation or the reboot-up operation. Alternatively, the fuse array unit 231 may sequentially output the Kth to Nth fuse data F_DATA<K:N> from the partial fuse region including the Kth to Nth fuse cells CK to CN in response to the Kth to Nth fuse driving signals FD<K:N> which are sequentially activated during the MRD reboot-up operation.

A unique number may be assigned to each of the first to Nth fuse cells C1 to CN. The unique numbers may be defined by the fuse driving unit 210. That is, the unique numbers may be reflected on the first to Nth fuse driving signals FD<1:N>. The first to Nth fuse cells C1 to CN may sequentially output the first to Nth fuse data F_DATA 1:N> corresponding to the entire fuse region according to the unique numbers, during the boot-up operation or the reboot-up operation. Furthermore, the Kth to Nth fuse cells CK to CN among the first to Nth fuse cells C1 to CN may sequentially output the Kth to Nth fuse data F_DATA<K:N> corresponding to the partial fuse region according to the unique numbers, during the MRD reboot-up operation. For reference, the Kth fuse data F_DATA<K> may be outputted from the Kth fuse cell CK ruptured in the program operation or an additional program operation which is performed after the program operation. That is the partial fuse region comprises the Kth fuse cell CK and (K+1)th to Nth fuse cells CK+1 to CN having a later number than the Kth fuse cell CK.

The fuse storage unit 233 may include the first to Nth latches LAT1 to LATN. The fuse storage unit 233 may sequentially store the first to Nth fuse data F_DATA<1:N>, which are sequentially outputted from the first to Nth fuse cells C1 to CN, in the first to Nth latches LAT1 to LATN, respectively, in response to the first to Nth latch driving signals LT<1.:N>. The first to Nth latches LAT1 to LATN may correspond one-to-one to the first to Nth fuse cells C1 to CN.

A unique number may be assigned to each of the first to Nth latches LAT1 to LATN. The unique numbers may also be defined by the fuse driving unit 210. That is, the unique numbers may be reflected on the first to Nth latch driving signals LT<1:N>. The first to Nth latches LAT1 to LATN may sequentially store the first to Nth fuse data F_DATA<1:N> corresponding to the entire fuse region according to the unique numbers during the boot-up operation or the reboot-up operation. Furthermore, the Kth to Nth latches LATK to

LATN among the first to Nth latches LAT1 to LATN may sequentially store the Kth to Nth fuse data F_DATA<K:N> corresponding to the partial fuse region according to the unique numbers, during the MRD reboot-up operation.

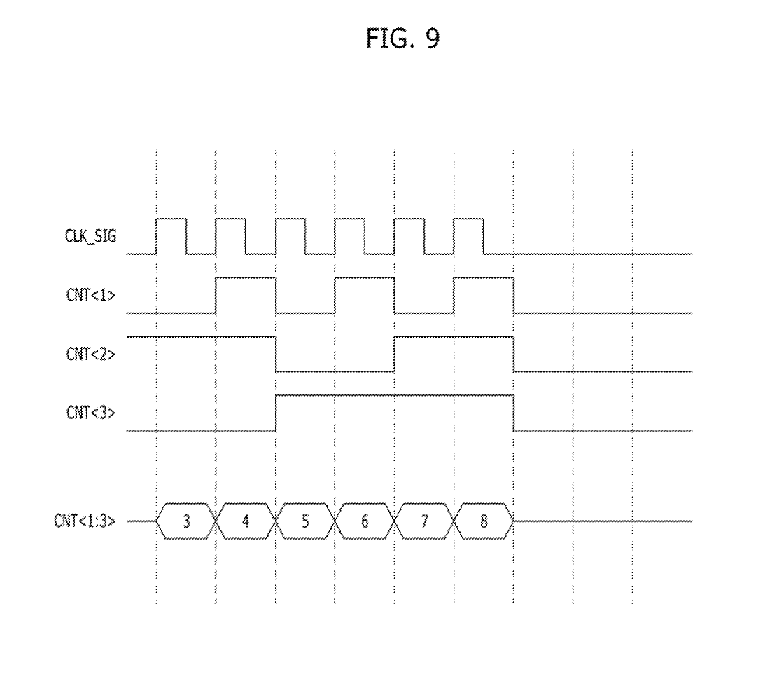

Hereafter, a method of driving the semiconductor device configured in the above manner will be described with reference to FIGS. 8 and 9.

First, the semiconductor device may perform a program operation. The program operation may be performed in a first test mode as follows.

For example, the fuse array unit 231 may rupture one or more of the first to Nth fuse cells C1 to CN in response to the fuse select signal' MRD<1:M> and the rupture enable signal RUP_EN. The fuse select signal MRD<1:M> may include an address signal indicating one or more of the first to Nth fuse cells C1 to CN included in the fuse array unit 231.

Then, the semiconductor device may perform the boot-up operation. The boot-up operation may be performed during an initial operation period during a normal mode. The boot-up operation may be performed as follows.

The periodic signal generation unit 110 may generate the periodic signal CLK_SIG in response to the first boot-up signal BT, and the boot-up select signal generation unit 130 may generate the boot-up select signal MRDI<1:M> of which all bits have a low level. The counter 211 may generate the counting signal CNT<1:M> in response to the periodic signal CLK_SIG and the boot-up select signal MRDI<1:M>. This will be described in more detail with reference to FIG. 8.

FIG. 8 is a timing diagram for explaining an operation of the counter 211 during the boot-up operation. A three-bit counter including first to third flip-flops DFF1 to DFF3 will be taken as an example of the counter 211.

Referring to FIG. 8, the counter 211 may generate the counting signal CNT<1:3> of ‘000’ as a default counting signal before the boot-up operation starts. Since the boot-up select signal MRDI<1:3> of ‘000’ is inputted to the counter 211, the counting signal CNT<1:3> may maintain the initial value of ‘000’,

Then, when the first boot-up signal BT corresponding to the boot-up operation is activated, the periodic signal generation unit 110 may generate the periodic signal CLK_SIG, and the counter 211 may generate the counting signal CNT<1:3> having a counting value which sequentially increases in response to the periodic signal CLK_SIG. For example, the counter 211 may generate the counting signal CNT<1:3> which is counted from ‘000’ to ‘111’.

Thus, the decoding unit 213 may sequentially generate first to eighth fuse driving signals FD<1:8> and first to eighth latch driving signals LT<1:8> in response to the counting signal CNT<1:3> having the counting value which sequentially increases from ‘1’ to ‘8’. Then, the fuse array unit 231 may sequentially output the first to eighth fuse data F_DATA<1:8> from the first to eighth fuse cells C1 to C8 in response to the first to eighth fuse driving signals FD<1:8>. The fuse storage unit 233 may sequentially store the first to eighth fuse data F_DATA<1:8> in the first to eighth latches LAT1 to LAT8, respectively, in response to the first to eighth latch driving signals LT<1:8>.

Thus, the semiconductor device may sequentially store the first to eighth fuse data F_DATA<1:8>, outputted from the entire fuse region including the first to eighth fuse cells C1 to C8, in the entire latch region including the first to eighth latches LAT1 to LAT8, during the boot-up operation.

Then, the semiconductor device may perform the MRD reboot-up operation. The MRD reboot-up operation may be performed in a second test mode that is different from the first test mode in which the program operation is performed. The MRD reboot-up operation may be performed to verify whether the program operation was normally performed, or to update the Kth to Nth fuse data F_DATA<:K:N>. For reference, when the MRD reboot-up operation is performed to update the Kth to Nth fuse data F_DATA<K:N>, an additional program operation may be performed prior to the MRD reboot-up operation. The additional program operation may be performed in the same manner as the program operation which is performed in the first test mode. However, the additional program operation may be performed on the same fuse cell or different fuse cells in another test mode that is different from the first test mode. The MRD reboot-up operation may be performed as follows.

The periodic signal generation unit 110 may generate the periodic signal CLK_SIG in response to the second boot-up signal MRD_RBT. The boot-up select signal generation unit 130 may generate the boot-up select signal MRDI<1:M> in response to the fuse select signal MRD<1:M> and the second boot-up signal MRD_RBT. The fuse select signal MRD<1:M> may include an address signal indicating the fuse cells ruptured during the additional program operation. The counter 211 may generate the counting signal CNT<1:M> corresponding to the partial fuse region in response to the periodic signal CLK SIG and the boot-up select signal MRDI<1:M>. This will be described in more detail with reference to FIG. 9.

FIG. 9 is a timing diagram for explaining the operation of the counter 211 during the MRD reboot-up operation. A three-bit counter including first to third flip-flops DFF1 to DFF3 will be taken as an example of the counter 211. Furthermore, in this example, a boot-up select signal MRDI<1:3> of ‘010’ is inputted to the counter 211.

Referring to FIG. 9, the counter 211 may generate the counting signal CNT<1:3> of ‘000’ as a default counting signal before the MRD reboot-up operation is started. At this time, since the boot-up select signal MRDI<1:3> of ‘010’ is inputted to the counter 211, the initial value of the counting signal CNT<1;3> may be change to ‘010’.

In this state, when the second boot-up signal MRD_RBT corresponding to the MRD reboot-up operation is activated, the periodic signal generation unit 110 may generate the periodic signal CLK_SIG, and the counter 211 may generate the counting signal CNT<1:3> having a counting value which sequentially increases, in response to the periodic signal CLK_SIG. For example, the counter 211 may generate the counting signal' CNT<1:3> which is counted from ‘010’ to ‘111’.

Thus, the decoding unit 213 may sequentially generate the third to eighth fuse driving signals FD<3:8> and the third to eighth latch driving signals LT<3:8> in response to the counting signal CNT<1:3> having a counting value which sequentially increases from ‘3’ to ‘8’. Then, the fuse array unit 231 may sequentially output the third to eighth fuse data F_DATA<3:8> from the third to eighth fuse cells C3 to C8 in response to the third to eighth fuse driving signals FD<3:8>. The fuse storage unit 233 may sequentially store the third to eighth fuse data F_DATA<3:8> in the third to eighth latches LAT3 to LAT8, respectively, in response to the third to eighth latch driving signals LT<3:8.

Therefore, the semiconductor device may sequentially store the third to eighth fuse data F_DATA<3:8> outputted from a partial fuse region including the third to eighth fuse cells C3 to C8, in a partial latch region including the third to eighth latches LAT3 to LAT8 during the MRD reboot-up operation.

The semiconductor device may perform a reboot-up operation. The reboot-up operation may be performed in a third test mode. The reboot-up operation may be performed in order to verify whether the program operation was normally performed or to update the first to Nth fuse data F_DATA<1:N>. Although the reboot-up operation is performed in the third test mode, the reboot-up operation may be performed in substantially the same manner as the boot-up operation, Thus, detailed descriptions of the reboot-up operation are omitted herein.

A semiconductor device in accordance with the embodiments of the present invention may reset the initial value of the counter 211 during the MRD reboot-up operation, and thus perform the reboot-up operation on a partial fuse region instead of the entire fuse region.

In accordance with the embodiments of the present invention, the semiconductor device may perform a reboot-up operation on partial fuse cells, thereby reducing the time required for the reboot-up operation.

Although various embodiments have been described for illustrative purposes it will be apparent to those skilled in the art that various changes and modifications may be made without departing from the spirit and scope of the invention as defined in the following claims.

For example, the position and type of the logic gates and transistors used in the above-described embodiments may be different depending on the polarities of input signals.

1. A semiconductor device comprising:
a control block generating a boot-up select signal in response to a boot-up mode signal and a fuse select signal; and
a fuse block performing a program operation of rupturing one or more first fuse cells among a plurality of fuse cells in response to the fuse select signal, and performing a boot-up operation on a partial fuse region including the one or more first fuse cells in response to the boot-up select signal;
wherein the fuse block comprises a counter generating a counting signal corresponding to the first fuse cells in response to a periodic signal and the boot-up select signal and determining an initial value of the counting signal in response to a plurality of bits included in the boot-up select signal.

2. The semiconductor device of claim 1, wherein a unique number is assigned to each of the plurality of fuse cells, and
the partial fuse region comprises the one or more first fuse cells and one or more second fuse cells having a later number than the one or more first fuse cells.

3. The semiconductor device of claim 1, wherein the control block generates the periodic signal in response to the boot-up mode signal, and
the fuse block performs the boot-up operation in response to the periodic signal.

4. The semiconductor device of claim 3, wherein the fuse block comprises:
a fuse driving unit generating a latch driving signal and a fuse driving signal corresponding to the partial fuse region in response to the boot-up select signal and the periodic signal; and
a fuse circuit unit performing the boot-up operation on the partial fuse region in response to the fuse driving signal and the latch driving signal.

5. The semiconductor device of claim 4, wherein the fuse driving unit comprises:
the counter; and
a decoding unit generating the fuse driving signal and the latch driving signal by decoding the counting signal.

6. The semiconductor device of claim 5, wherein the counter comprises:
a plurality of flip-flops corresponding one-to-one to a plurality of bits included in the counting signal.

7. The semiconductor device of claim 4, wherein the fuse circuit unit performs the program operation of rupturing the one or more first fuse cells in response to the fuse select signal and a rupture enable signal, and
the program operation and the boot-up operation are performed in different test modes.

8. The semiconductor device of claim 7, wherein the fuse circuit unit comprises:
a fuse array unit comprising the plurality of fuse cells, and performing the program operation on the one or more first fuse cells in response to the fuse select signal and the rupture enable signal, and outputting partial fuse data corresponding to the partial fuse region in response to the fuse driving signal; and
a fuse storage unit comprising a plurality of latches corresponding one-to-one to the plurality of fuse cells, and storing the partial fuse data in corresponding latches in response to the latch driving signal.

9. A semiconductor device comprising:
a boot-up select signal generation unit generating a boot-up select signal in response to a boot-up mode signal and a fuse select signal;
a fuse driving unit sequentially activating Kth to Nth fuse driving signals, and sequentially activating Kth to Nth latch driving signals, in response to the boot-up select signal, where N is a natural number greater than or equal to 2 and K is a natural number between 1 and N; and
a fuse circuit unit performing a program operation of rupturing one or more fuse cells including the Kth fuse cell in response to the fuse select signal, and performing a boot-up operation on the Kth fuse cell to Nth fuse cell in response to the Kth to Nth fuse driving signals and Kth to Nth latch driving signals,
wherein the fuse driving unit comprises a counter generating a counting signal corresponding to the Kth to Nth fuse cells in response to the periodic signal and the boot-up select signal, and determining an initial value of the counting signal in response to a plurality of bits included in the boot-up select signal.

10. The semiconductor device of claim 9, further comprising:
a periodic signal generation unit generating the periodic signal in response to the boot-up mode signal.

11. The semiconductor device of claim 10, wherein the fuse driving unit further comprises:
a decoding unit generating the Kth to Nth fuse driving signals and the Kth to Nth latch driving signals by decoding the counting signal.

12. The semiconductor device of claim 11, wherein the counter comprises:
a plurality of flip-flops corresponding one-to-one to a plurality of bits included in the counting signal.

13. The semiconductor device of claim 9, wherein the fuse circuit unit performs the program operation of rupturing the one or more fuse cells in response to the fuse select signal and a rupture enable signal, and
the program operation and the boot-up operation are performed in different test modes.

14. The semiconductor device of claim 13, wherein the fuse circuit unit comprises:
a fuse array unit comprising the first to Nth fuse cells, and performing the program operation on the one or more fuse cells including the Kth fuse cell in response to the fuse select signal and the rupture enable signal, and outputting the Kth to Nth fuse data corresponding to the Kth to Nth fuse cells in response to the Kth to Nth fuse driving signals; and
a fuse storage unit comprising first to Nth latches corresponding one-to-one to the first to Nth fuse cells, and storing the Kth to Nth fuse data in the Kth to Nth latches in response to the Kth to Nth latch driving signals.

15. A method of driving a semiconductor device, comprising:
performing a boot-up operation on an entire fuse region including a plurality of fuse cells during a normal mode;
performing a program operation of rupturing one or more fuse cells during a first test mode; and
performing a first reboot-up operation on a partial fuse region including the one or more fuse cells during a second test mode,
wherein the performing of the first reboot-up operation comprises:
entering the second test mode;
determines an initial value of a counting signal in response to a fuse select signal;
generating the counting signal by counting a periodic signal by a value corresponding to the partial fuse region from the initial value; and
generating a fuse driving signal and a latch driving signal by decoding the counting signal.

16. The method of claim 15, wherein the performing of the program operation comprises:
entering the first test mode; and
rupturing the one or more fuse cells in response to a fuse select signal.

17. The method of claim 15, wherein the performing of the first reboot-up operation further comprises:
outputting fuse data from the partial fuse region in response to the fuse driving signal; and
storing the fuse data outputted from the partial fuse region in a partial latch region in response to the latch driving signal.

18. The method of claim 15, wherein the performing of the boot-up operation comprises:
entering the normal mode;
generating a counting signal by counting a periodic signal;
generating a fuse driving signal and a latch driving signal by decoding the counting signal;
outputting fuse data from the entire fuse region in response to the fuse driving signal; and
storing the fuse data outputted from the entire fuse region in an entire latch region in response to the latch driving signal.

19. The method of claim 15, further comprising:
performing a second reboot-up operation on the entire fuse region during a third test mode.

20. The method of claim 19, wherein the performing of the second reboot-up operation comprises:
entering the third test mode;
generating a counting signal by counting a periodic signal corresponding to the entire fuse region;
generating a fuse driving signal and a latch driving signal by decoding the counting signal;
outputting fuse data from the entire fuse region in response to the fuse driving signal; and
storing the fuse data outputted from the entire fuse region in an entire latch region in response to the latch driving signal.
